(19) United States
(12) Patent Application Publication
(10) Pub. No.: US 2004/0032300 A1
(43) Pub. Date: Feb. 19, 2004

(54) Multi-phase oscillator and method therefor

(75) Inventors: Geertjan Joordens, Santa Clara, CA (US); Wenyi Song, San Jose, CA (US)

Correspondence Address: PHILIPS ELECTRONICS NORTH AMERICA CORPORATION, INTELLECTUAL PROPERTY & STANDARDS, 1109 MCKAY DRIVE, M/S-41SJ, SAN JOSE, CA, 95131, US

(73) Assignee: KONINKLIJKE PHILIPS ELECTRONICS N.V.

(21) Appl. No.: 10/224,018

(22) Filed: Aug. 19, 2002

(51) Int. Cl. H03B 1/00

(52) U.S. Cl. 331/57

(57) ABSTRACT

The invention relates to a multi-phase inverter ring oscillator generating multiple output signals arranged in groups of four. In an example embodiment, an even number of inverters are coupled together in a cascaded series, each inverter has an input and an output, the output of one inverter is coupled to the input of a next sequential one of the inverters. There are a corresponding number of cross-coupled transistors. Each cross-coupled transistor couples the input of one inverter to the output of the next sequential one of the inverters. In a particular example embodiment, a four-phase inverter ring oscillator generates four output signals that are shifted 90° in phase and may be used to generate 50% duty cycle clocks.

### FIELD OF THE INVENTION

The invention relates to integrated circuit technology. In particular, the invention relates to an oscillator that may be configured with a four, eight, twelve, sixteen, or more phases.

### BACKGROUND

Ring oscillators are used in a multitude of electronics applications. They are commonly used in Phase Locked Loops (PLLs) and Clock and Data Recovery (CDR). The frequency may be tuned by its voltage as in a Voltage-Controlled Oscillator (VCO) or by its current as in a Current Controlled Oscillator (CCO).

An inverter ring oscillator comprises a number of inverters in a ring. The frequency of the oscillation depends on the number of inverters and the delay of one inverter cell. The delay may be made dependent by its voltage as in a Voltage-Controlled Oscillator (VCO) or by its current as in a Current Controlled Oscillator (CCO).

A common ring oscillator is the 3 or 5 inverter ring oscillator. The circuits generate odd phases, 3 or 5 and odd phase differences between the internal node (360/3 or 360/5).

Some applications (e.g., CDR) require 4-phase signals or 50% duty cycle clocks running at high speeds. A four-inverter ring oscillator may be used. However, an oscillator with an even number of inverting stages has a stable state. Thus, additional circuits are needed to start up and sustain the oscillation. FIG. 1 shows a conventional approach. A circuit 100 has inverter stages 110, 120, 130, and 140 respectively. Output of inverter 110 at N1 is coupled to the input of inverter 120. Output of inverter 120 at N2 is coupled to input of inverter 130. Output of inverter 130 at N3 is coupled to input of inverter 140. Output of inverter 140 at N4 is coupled to input of inverter 110. An inverter-based latch 150 couples N2 and N4. Likewise, another inverter-based latch 160 couples N1 and N3. These latches 150, 160 provide a negative resistance between opposite nodes to start and sustain the oscillation.

Although the conventional circuit provides four phases, the latches reduce the performance of the circuit. The latches limit the frequency at which the oscillator may operate. In addition, the latches require more energy to switch.

There exists a need for a ring oscillator that provides 4-phase signals without limiting the operating frequency and eliminates the shortcomings of ring oscillators having an odd number of stages.

### SUMMARY OF THE INVENTION

The present invention is exemplified in a number of implementations, one of which is summarized below. In an example embodiment, a multi-phase ring oscillator comprises an even number of inverters coupled together in a cascaded series, each inverter having an input and an output, the output of one inverter coupled to the input of a next sequential one of the inverters. There are a corresponding number of cross-coupled transistors, each cross-coupled transistor coupling the input of one inverter to the output of the next sequential one of the inverters.

In another embodiment, according to the present invention there is an integrated circuit layout comprising a CMOS four-phase ring oscillator, the layout comprises, four CMOS inverters coupled together in a cascaded series, each inverter having an input and an output, the output of one inverter coupled to the input of a next sequential one of the inverters. Also, there are four N-MOS cross-coupled transistors, each cross-coupled transistor coupling the input of one inverter to the output of the next sequential one of the inverters, wherein the N-diffusion is commonly shared between N-MOS transistors of the inverters and the N-MOS cross-coupled transistors, wherein the N-diffusion and P-diffusion areas are about the same size, the layout having a predetermined minimized area.

In yet another embodiment, according to the present invention there is a method of using a multi-phase oscillator comprising providing an even number of inverters; each inverter has an input and an output. The output of one inverter is coupled to the input of a next sequential one of the inverters in a cascaded series. A corresponding number of cross-coupled transistors is provided and each cross-coupled transistor is coupled to the input of one inverter to the output of the next sequential one of the inverters. From the multi-phase ring oscillator, an output signal is obtained. A feature of this embodiment is that an even number of inverters, divisible by four, is provided. In an additional feature of this embodiment, the output signal obtained comprises receiving an N-number of signals that are 360°/N out of phase with one another, where N=4, 8, 12, 16, 32, 36, 40, . . . etc.

The above summaries of the present invention are not intended to represent each disclosed embodiment, or every aspect, of the present invention. Other aspects and example embodiments are provided in the figures and the detailed description that follows.

### BRIEF DESCRIPTION OF THE DRAWINGS

The invention may be more completely understood in consideration of the following detailed description of various embodiments of the invention in connection with the accompanying drawings, in which:

FIG. 1.(Prior Art) is an example of a conventional 4-phase oscillator circuit using inverters;

FIG. 2 is an example embodiment of a 4-phase oscillator according to present invention;

FIG. 2A illustrates the operation of the embodiment of FIG. 2 with N1 initialized with a logic 1 signal at T₀;

FIG. 2B illustrates the operation of the embodiment of FIG. 2 with N1 with a logic 0 signal at T₀+ΔT;

FIG. 3A illustrates an implementation of FIG. 2 at the transistor level with active PMOS pull up;

FIG. 3B depicts the arrangement of the circuit of FIG. 3A as laid out as a block in an integrated circuit;

FIG. 4 depicts the example embodiment of FIG. 2 with nodes forming differential signals;

FIG. 5A shows a block diagram of a 2-stage differential ring oscillator according to an example embodiment of the present invention;

FIG. 5B depicts a differential cell that may be used in a ring oscillator according to an embodiment of the present invention;

FIG. 6 depicts plots of the output waveforms of the example embodiment of FIG. 4;

FIG. 7 is example embodiment of an 8-phase oscillator according to present invention;

FIG. 8 depicts plots of the output waveforms of the example embodiment of FIG. 7; and

FIG. 9 depicts a modification of the circuit of FIG. 3 in which passive a PMOS pull-up is used.

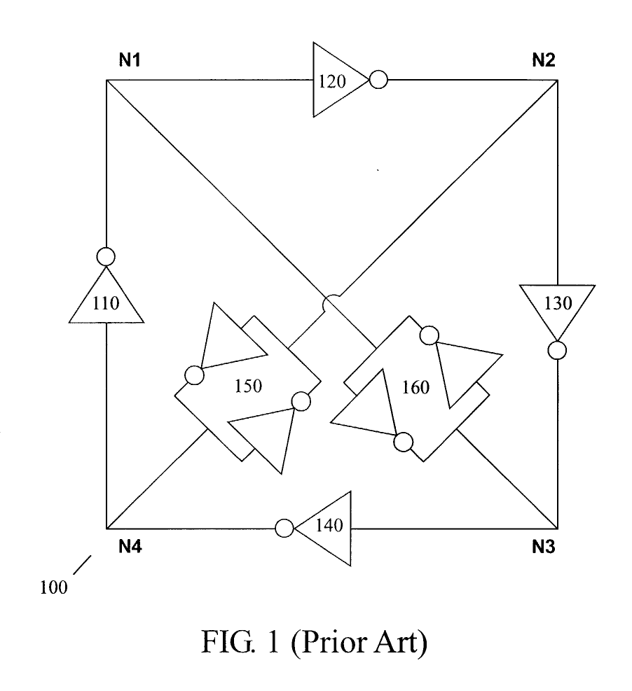

### DETAILED EMBODIMENTS

The present invention permits the generating of four-phase signals with an even number of inverters. Having an even number of inverters makes the circuit symmetrical. The output signals are symmetrical and may be treated as single-ended or differential. The number of components is minimized to reduce the area consumed in an integrated circuit design. The invention may be implemented in CMOS technology. However, the present invention is applicable to bipolar, BiCMOS, ECL or other IC processing technology, as well. The underlying fabrication technology may include silicon (Si), gallium-arsenide (GaAs), silicon-on-insulator (SOI) et al.

In example embodiment according to the present invention, four inverters are coupled together at their respective input and output terminals. N-MOS transistors cross couple the input of one inverter with the output of its neighbor. The N-MOS transistor pulls down the opposite node at the output of each inverter.

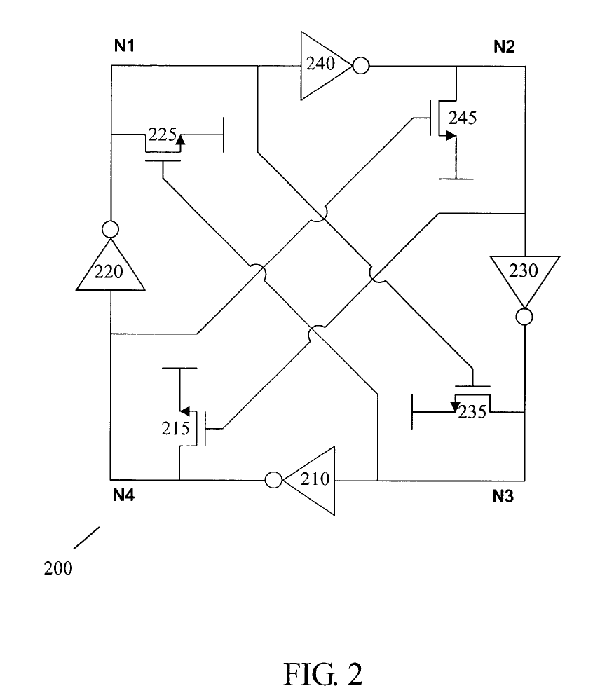

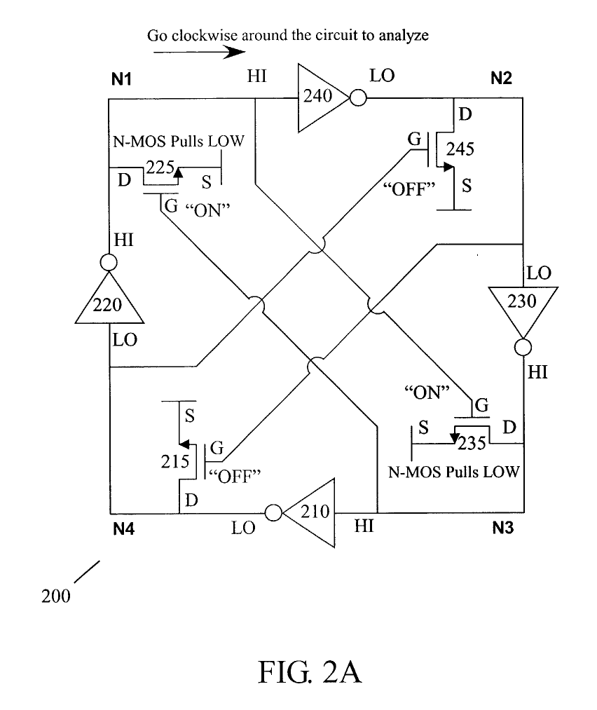

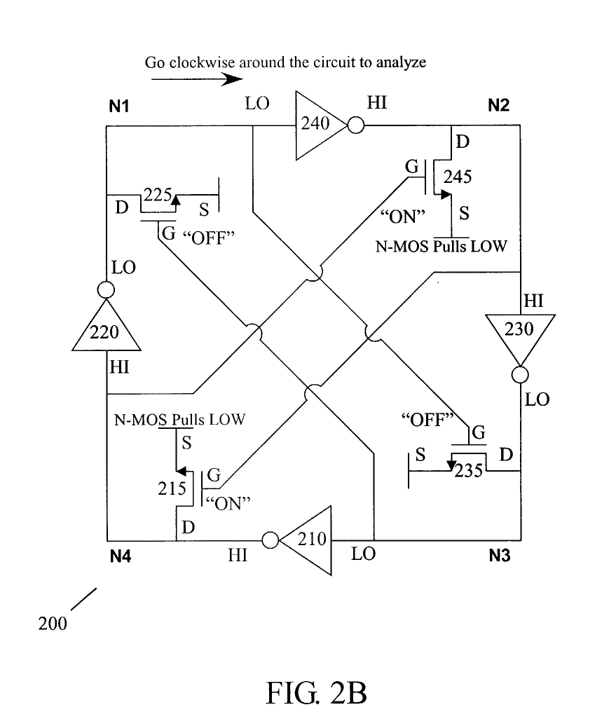

Refer to FIG. 2. The circuit 200 comprises four inverters 210, 220, 230, and 240 with their inputs and outputs coupled to one another at nodes N1, N2, N3, and N4. N-MOS transistors 215, 225, 235, and 245 cross couple the input of one inverter to the output of another. The input of inverter 210 at N3 is coupled to the gate of N-MOS transistor 225. The drain of N-MOS transistor 215 is coupled to the output of Inverter 210 at N4. Likewise, the input of inverter 220 is coupled to the gate of N-MOS transistor 245 at N4. The drain of N-MOS transistor 225 is coupled to the output of inverter 220 at N1. The input of inverter 240 is coupled to the gate of N-MOS transistor 235 and the output of inverter 240 is coupled to the drain of N-MOS transistor 245. The input of inverter 230 is coupled to the gate of N-MOS transistor 215. The drain of N-MOS transistor is coupled to the output of inverter 240. The source terminals of N-MOS transistors 215, 225, 23, and 245 are coupled to a reference voltage V_{SS}. The drain terminals of the N-MOS transistors are node voltages VN1, VN2, VN3, and VN4. These node voltages are typically at a voltage V_{OSC}. For an example CMOS process, this may range from 1.8 volts to 6.5 volts. In some instances, V_{OSC} is at the rail voltage V_{DD}. In another example CMOS process, VO_{sc} may range from about 0.6 v to about 1.1 v. The node voltage may be any voltage suitable for the given integrated circuit technology. Typically, V_{SS} is a zero voltage. For the circuit to function, the voltage difference between the oscillator voltage V_{OSC} and V_{SS} must be sufficiently large to exceed the MOS transistors' threshold voltages so that the transistors are switched on.

Refer to FIG. 2A. In operating circuit 200 according to an embodiment of the present invention we can observe the voltages present at N1, N2, N3, and N4. After the power supply of the circuit has been brought up, the oscillator 200 may be started by applying “high” signal at N1. A “high” signal typically would be V_{DD} and a “low” signal typically is V_{SS}. In CMOS the V_{DD} may range from 1.8 volts to 6.5 volts and V_{SS} is a ground reference of zero volts. The level of V_{DD} depends upon the specific CMOS fabrication technology in use. As mentioned earlier, alone the four inverters 221, 220, 230, and 240 will not oscillate because the voltages at the N1, N2, N3, and N4 are consistent. To better understand the operation of the circuit according to the present invention, the user proceeds from N1 of the circuit and goes clockwise through the schematic. At startup, time at zero (T₀), the voltage at N1 is “high.” The voltage at the drain of the N-MOS transistor 225 is “high” and the voltage of the gate of N-MOS transistor 235 is also “high,” both transistors being coupled to N1. Having passed through inverter 240, the voltage at N2 is “low.” The voltage at the drain of N-MOS transistor 245 is “low” and the voltage of the gate of N-MOS transistor 215 is also “low.” Having passed through inverter 230, the voltage at N3 is “high.” The voltage at the drain of N-MOS transistor 235 is “high” and the voltage at the gate of N-MOS transistor 225 is “high.” Having passed through inverter 210, the voltage at N4 is “low.” The voltage at the drain of N-MOS transistor 215 is “low” and the voltage at the gate of N-MOS transistor 245 is “low.” Note that the sources of the four N-MOS transistors 215, 225, 245, and 235 are coupled to V_{SS}. When an N-MOS transistor is switched on, the transistor acts as a pull-down. The drain voltage is pulled-down to V_{SS}, usually defined as the ground reference. Thus, N-MOS transistors 225, and 235 are switched on. Their respective gate and drain voltages are “high.” With their sources coupled to ground, they pull-down the N1 and N3 node voltage. N-MOS transistors 245, and 215 are switched off, since their gates are driven “low.” Also their respective drains are at “low” since the voltages at N2 and N4 are “low.”

At T₀+ΔT, the voltages at N1 and N3 are pulled down from their initial high state. The voltage at a node cannot be at two levels, simultaneously. The input of inverter 240 at N1 having been high is pulled to ground. A similar cycle begins at N1 started at its voltage being low. The voltage at the gate of N-MOS transistor 235 is low and the voltage at the drain of N-MOS transistor at high since the voltage at N1 having passed through inverter 240 is high at N2. The voltage at N3 is low having passed the voltage at N2 through inverter 230. The voltage at the drain of N-MOS 235 is low and the voltage at the gate of N-MOS transistor 225 is low. The voltage at N4 is high since the voltage at N3 passes through inverter 210. The voltage at the drain of N-MOS transistor 215 is high and the voltage at the gate of N-MOS transistor 245 is at high. Transistors 215 and 245 are switched on, their gates being driven high. Transistors 225 and 235 are switched off, their gates being driven low. Transistors 215 and 245 pull-down nodes N2 and N4 from their respective high states. Again, the voltages at N2 and N4 cannot be at two levels simultaneously. Consequently, there is instability introduced at nodes N2 and N4 as is on nodes N1 and N3 (as discussed in reference to FIG. 2A). The instability results in the circuit 200 producing an oscillating voltage at nodes N1, N2, N3, and N4. The N-MOS transistors 215 and 235 switch on and while N-MOS transistors 215 and 245 switch off and vice-versa. This switching drives the oscillation of circuit 200.

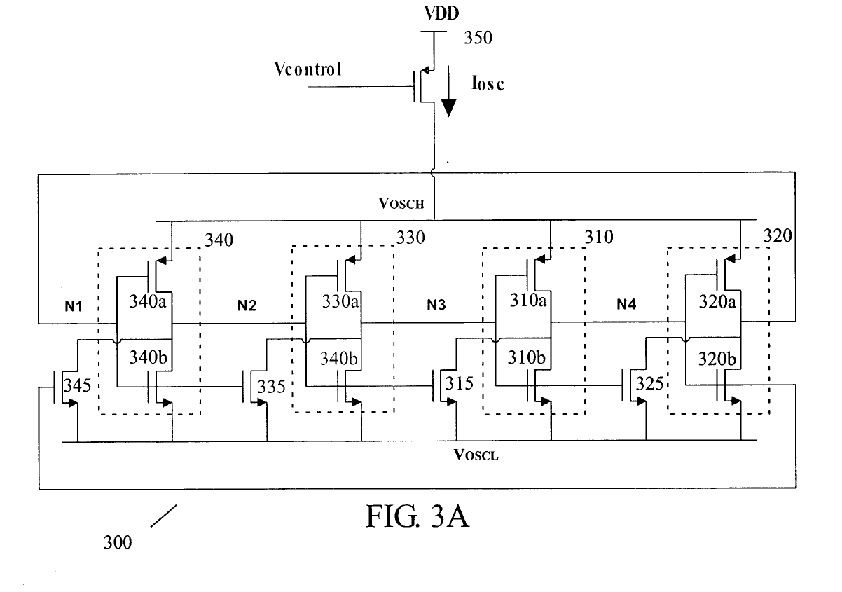

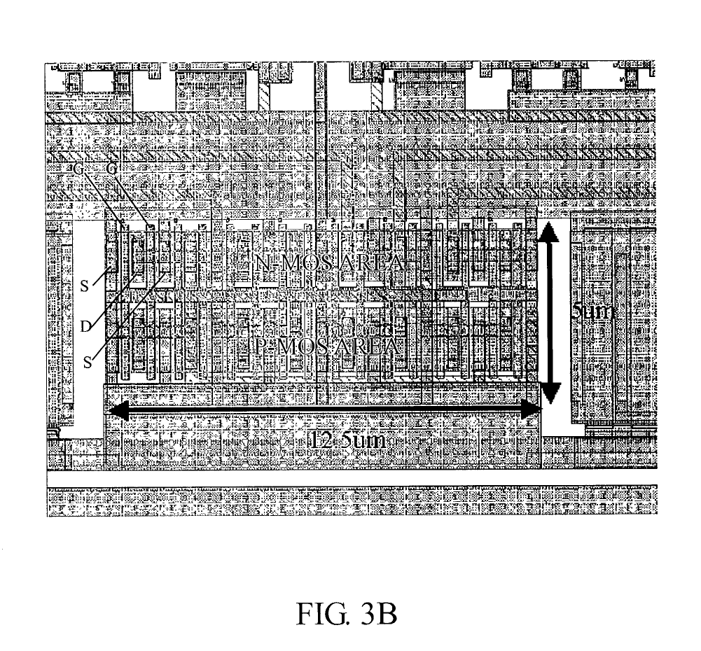

Refer to FIG. 3A. Circuit 300 is a schematic representation of FIG. 2 at the transistor level. Twelve transistors comprise the 4-phase oscillator. Inverters 310, 320, 330, and 340 are coupled to one another at their inputs and outputs. The sources 310a, 320a, 330a, and 340a P-MOS transistors of the inverters are connected to V_{OSCH}. As in FIG. 2, N-MOS transistors 315, 325, 335, and 345 cross couple inverters 310, 320, 330, and 340. The sources of the N-MOS transistors of the inverters 310, 320, 330, and 340 and of the N-MOS transistors 315, 325, 335, and 345 and coupled to V_{OSCL}. In a typical configuration, V_{OSCL} is set to V_{SS}. The frequency of this oscillator is controlled by a PMOS current source 350 coupled between V_{DD} and V_{OSCH}. The voltage applied to the gate at V_{Control} determines how much current I_{OSC} is supplied to the 4-phase oscillator. The resulting circuit 300 is a voltage-controlled oscillator (VCO). Thus, the inverters 310, 320, 330, and 340 are switching back and forth between V_{OSCH} and V_{SS}.

In another example embodiment according to the present invention, the PMOS current source 350 may be substituted by an NMOS current source (not illustrated). The NMOS current source is coupled to the V_{OSCL} nodes of the inverters. The inverters 310, 320, 330, and 340 switch back and forth between V_{DD} and V_{OSCL}. Other types of supplies may be coupled to the oscillator to provide frequency control, as well.

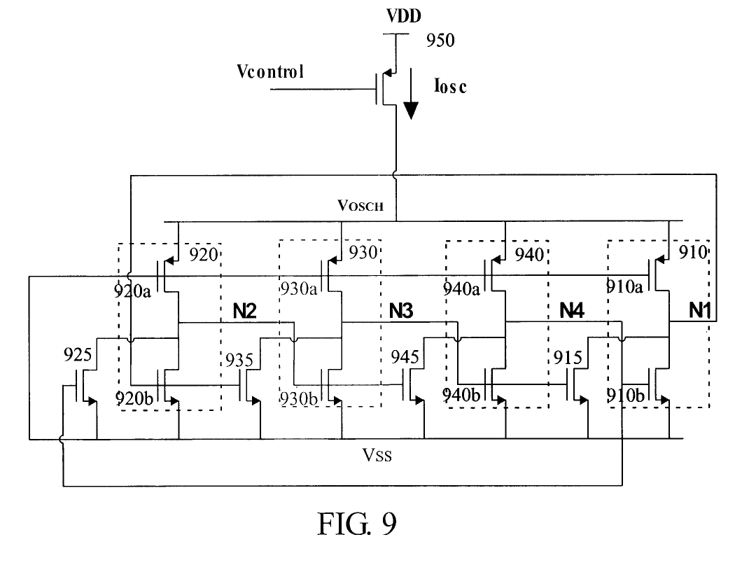

By using a passive PMOS pull-up in place of inverters providing an active PMOS pull-up, the circuit 300 of FIG. 3A may be modified. The gates of the PMOS transistors are coupled to ground. In this configuration, the voltage across the oscillator is less dependent on the frequency and current. Refer to FIG. 9. The gates of PMOS transistors 910a, 920a, 930a, and 940a are coupled to ground at V_{SS}. The layout of the circuit would be similar to that of FIG. 3B.

The 4-phase oscillator operates in the range of about 150 KHz to about 3.0 GHz. Typically, a preferred operating frequency is about 1.6 GHz. A lower limit is about 100 MHz. In some semiconductor processes, oscillators according to the present invention may be fabricated that can run at frequencies about 5 GHz or higher.

Refer to FIG. 3B. In laying out circuit 300, the number of N-MOS transistor is double the number of P-MOS transistors. Since P-MOS transistors are approximately double in size (owing to the lower gₘ), the area consumed by P-MOS and N-MOS transistors is about the same. The layout is straightforward and symmetrical. Thus, the speed of the circuit is enhanced. The circuit 300 is also very balanced, since the N-diffusion and P-diffusion areas are about the same size. Consequently, the capacitances are balanced between power and ground. The voltages at N1, N2, N3, and N4 are symmetrical in that the rising and falling edges are equal. In an example CMOS process with 0.20 μm process or less, the area of circuit depicted in FIG. 3A would be 12.51 μm×5 μm or about 63 μm². The drain, gate, and source are noted on the N-MOS transistor region. Process dimensions limit the maximum frequency.

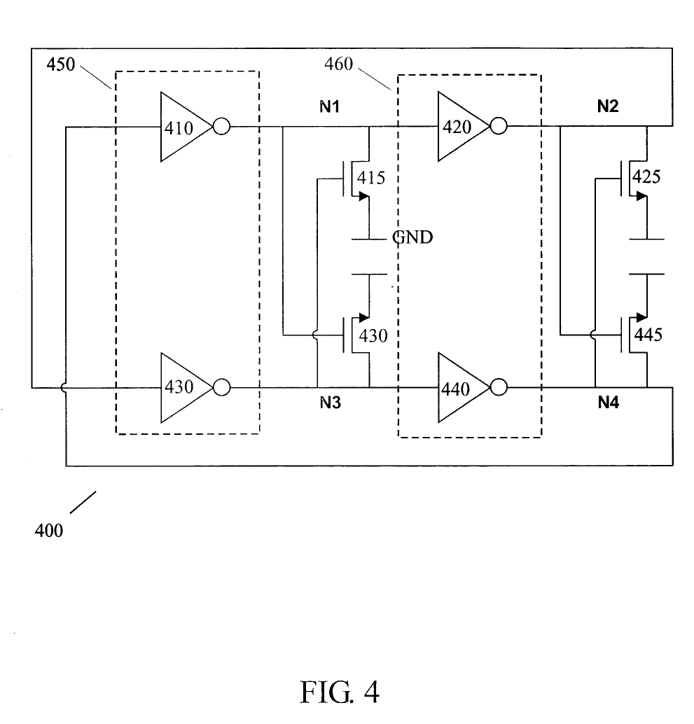

Refer to FIG. 4. The embodiment according to the present invention may be arranged in a circuit 400. Nodes N1, N3 and N2, N4 form differential signals. The differential oscillator has 2 gain stages; each gain stage has two inverters. Gain stage 450 has two inverters 410 and 430. Likewise, gain stage 460 has two inverters 420 and 440. At the output of each stage is a pair of cross-coupled N-MOS transistors (to provide the negative resistance). On the output of gain stage 450, transistors 415 and 430 provide the negative resistance. Correspondingly, the output of gain stage 460 transistors 425 and 445 provide the negative resistance. The common mode is ground.

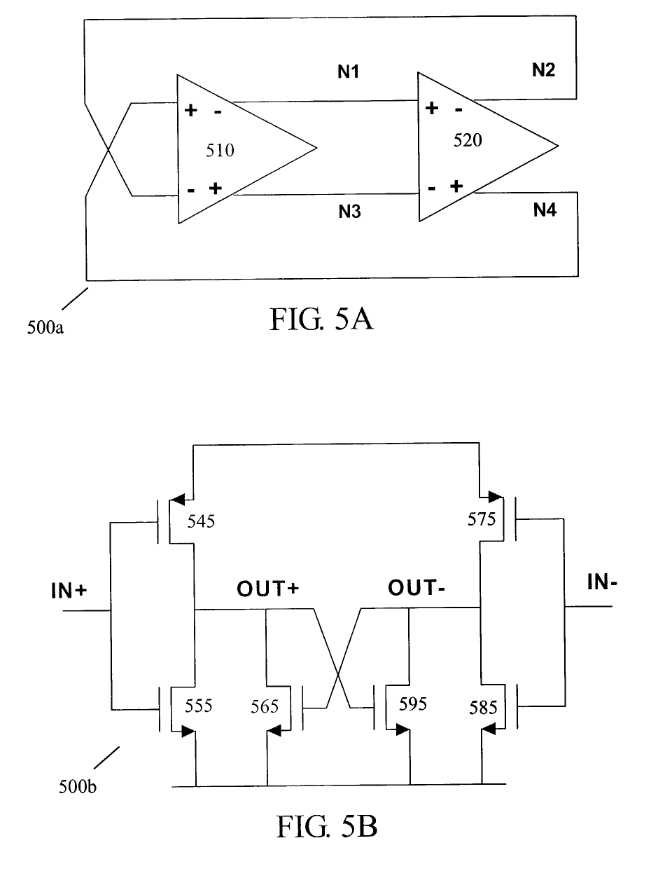

Refer to FIG. 5A. Circuit 500a depicts in block diagram form a 2-stage differential oscillator with stages 510 and 520.

Refer to FIG. 5B. Circuit 500b illustrates at the transistor level a differential cell 510 or 520 of FIG. 5a. Transistors 545 and 555 and transistors 575 and 585 comprise inverters. The inverters are cross-coupled with N-MOS transistors 565 and 595. At least two of these cells are used to build the 4-phase oscillator according to the present invention.

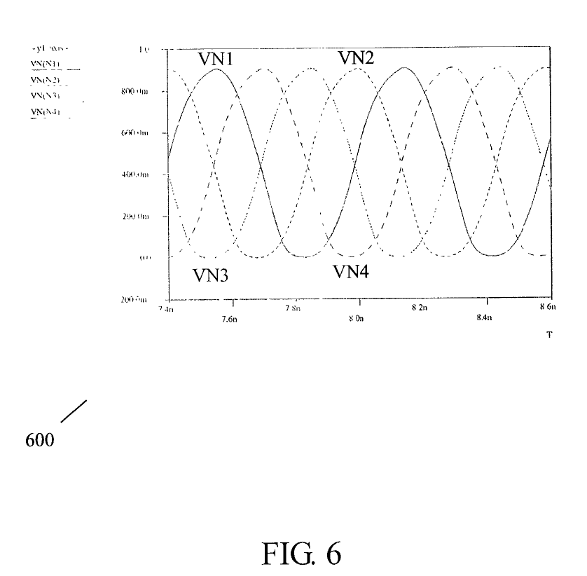

The oscillator according to the present invention provides four signals 90° out of phase with one another. Refer to FIG. 6. Plot 600 depicts the oscillation outputs at nodes N1, N2, N3, and N4. V_{N1} and V_{N3} provide opposite phases (180° out of phase) to generate a 50% duty cycle clock.

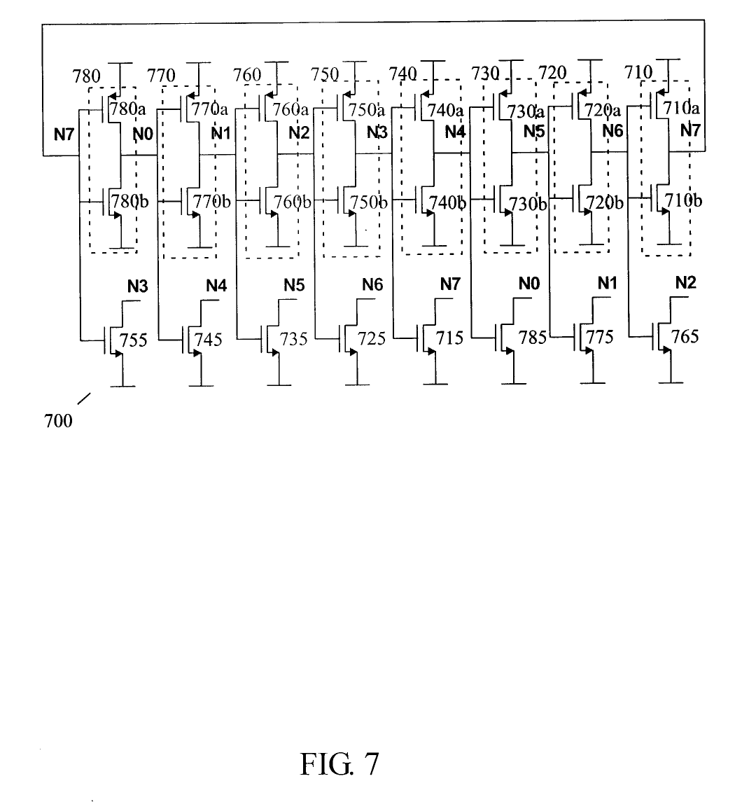

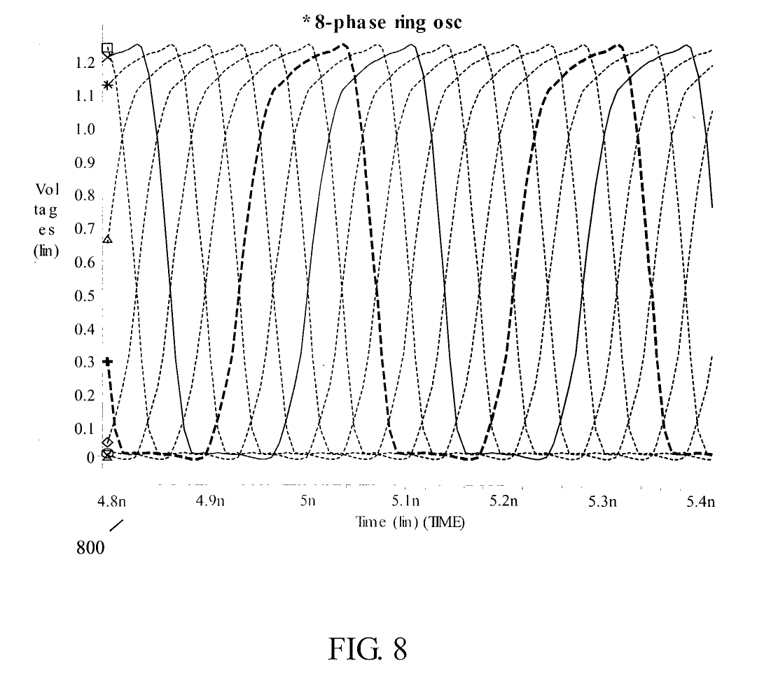

In another embodiment according to the present invention, an 8-phase oscillator may be constructed. Refer to FIG. 7. In circuit 700, there are eight inverter stages 710, 720, 730, 740, 750, 760, 770, and 780. N-MOS transistors 715, 725, 735, 745, 755, 765, 775 are cross-coupled to their respective inverters. The oscillator outputs at nodes N0, N1, N2, N3, N4, N5, N6, and N7 are 45° out of phase with one another. The waveforms of the 8-phase oscillator are depicted in plot 800 of FIG. 8. Operation and analysis of the circuit follows that presented in the description of FIGS. 2, 2A, 2B, and 3A.

Another embodiment according to the present invention may be built using P-MOS cross-coupled transistors as well. For a given circuit layout, the frequency of oscillation would be lower owing to lower gₘ. Also depending upon specific design requirements, CMOS depletion-mode transistors (e.g., the transistor is normally switched on and through gate voltage control may be switched off) may be used in place of typically used enhancement-mode transistors (e.g., the transistor is normally switched off and through gate voltage control may be switched on).

While the present invention has been described with reference to several particular example embodiments, those skilled in the art will recognize that many changes may be made thereto without departing from the spirit and scope of the present invention, which is set forth in the following claims.

What is claimed:

1. A multi-phase ring oscillator comprising:
an even number of inverters coupled together in a cascaded series, each inverter having an input and an output, the output of one inverter coupled to the input of a next sequential one of the inverters; and
a corresponding number of cross-coupled transistors, each cross-coupled transistor coupling the input of one inverter to the output of the next sequential one of the inverters.

2. The multi-phase ring oscillator of claim 1, wherein the even number of inverters and the respective corresponding cross-couple transistors is at least four.

3. The multi-phase ring oscillator of claim 2, wherein the even number of inverters respective corresponding cross-couple transistors is a number divisible by four.

3. The multi-phase ring oscillator of claim 1, wherein the multi-phase ring oscillator is fabricated from technologies selected from the following: CMOS, N-MOS, P-MOS, BiCMOS, Bipolar, ECL.

4. A CMOS multi-phase ring oscillator, the oscillator comprising;
an even number of inverters coupled together in a cascaded series, each inverter having an input and an output, the output of one inverter coupled to the input of a next sequential one of the inverters; and
a corresponding number of cross-coupled transistors, each cross-coupled transistor coupling the input of one inverter to the output of the next sequential one of the inverters.

5. The CMOS multi-phase ring oscillator of claim 4, wherein the cross-couple transistors are selected from the following: N-type, P-type.

6. The CMOS ring oscillator of claim 5, wherein the cross-coupled transistors are selected from the following: Enhancement-Mode, Depletion-Mode.

7. A CMOS ring oscillator having four output signals shifted 90° in phase, the ring oscillator comprising:
four inverters coupled together in a cascaded series, each inverter having an input and an output, the output of one inverter coupled to the input of a next sequential one of the inverters; and
four cross-coupled transistors, each cross-coupled transistor coupling the input of one inverter to the output of the next sequential one of the inverters.

8. The CMOS ring oscillator of claim 7, wherein each cross-coupled transistor comprises an N-MOS transistor having a drain, gate, and a source, the gate coupling the input of one inverter, the drain coupling the output of the next sequential one of the inverters, and the source coupled to ground.

9. A CMOS ring oscillator having eight output signals shifted 45° in phase, the ring oscillator comprising:
eight inverters coupled together in a cascaded series, each inverter having an input and an output, the output of one inverter coupled to the input of a next sequential one of the inverters; and
eight cross-coupled transistors, each cross-coupled transistor coupling the input of one inverter to the output of the next sequential one of the inverters.

10. The CMOS ring oscillator of claim 9, wherein each cross-coupled transistor comprises an N-MOS transistor having a drain, gate, and a source, the gate coupling the input of one inverter, the drain coupling the output of the next sequential one of the inverters, and the source coupled to ground.

11. An integrated circuit layout comprising a CMOS multi-phase ring oscillator, the layout comprising:
an even number of CMOS inverters coupled together in a cascaded series, each inverter having an input and an output, the output of one inverter coupled to the input of a next sequential one of the inverters; and
a corresponding number N-MOS cross-coupled transistors, each cross-coupled transistor coupling the input of one inverter to the output of the next sequential one of the inverters, wherein the N-diffusion is commonly shared between N-MOS transistors of the inverters and the N-MOS cross-coupled transistors, wherein the N-diffusion and P-diffusion areas are about the same size, the layout having a predetermined minimized area.

12. The integrated circuit layout of claim 11, wherein the even number of CMOS inverters and the respective N-MOS cross-coupled transistors is at least four.

13. The integrated circuit layout of claim 12, wherein the even number of inverters and the respective N-MOS cross-couple transistors is a number divisible by four.

14. An integrated circuit layout comprising a CMOS four-phase ring oscillator, the layout comprising:
four CMOS inverters coupled together in a cascaded series, each inverter having an input and an output, the output of one inverter coupled to the input of a next sequential one of the inverters; and
four N-MOS cross-coupled transistors, each cross-coupled transistor coupling the input of one inverter to the output of the next sequential one of the inverters, wherein the N-diffusion is commonly shared between N-MOS transistors of the inverters and the N-MOS cross-coupled transistors, wherein the N-diffusion and P-diffusion areas are about the same size, the layout having a predetermined minimized area.

15. An integrated circuit layout comprising a CMOS eight-phase ring oscillator, the layout comprising:
eight CMOS inverters coupled together in a cascaded series, each inverter having an input and an output, the output of one inverter coupled to the input of a next sequential one of the inverters; and
eight N-MOS cross-coupled transistors, each cross-coupled transistor coupling the input of one inverter to the output of the next sequential one of the inverters, wherein the N-diffusion is commonly shared between N-MOS transistors of the inverters and the N-MOS cross-coupled transistors, wherein the N-diffusion and P-diffusion areas are about the same size, the layout having a predetermined minimized area.

16. A method of using a multi-phase ring oscillator comprising:
providing an even number of inverters, each inverter having an input and an output;
coupling the output of one inverter coupled to the input of a next sequential one of the inverters in a cascaded series; and
providing a corresponding number of cross-coupled transistors;
cross-coupling each cross-coupled transistor to the input of one inverter to the output of the next sequential one of the inverters; and
obtaining an output signal from the multi-phase ring oscillator.

17. The method of claim 16,
wherein providing an even number of inverters further comprises having the even-number be divisible by four.

18. The method of claim 17 wherein, obtaining the output signal comprises receiving an N-number of signals that are 360°/N out of phase with one another, where N=4, 8, 12, 16, 32, 36, 40, . . . etc.

19. A method of using a four-phase ring oscillator comprising:
providing four inverters, each inverter having an input and an output;
coupling the output of one inverter coupled to the input of a next sequential one of the inverters in a cascaded series; and
providing a corresponding number of cross-coupled transistors;
cross-coupling each cross-coupled transistor to the input of one inverter to the output of the next sequential one of the inverters; and
obtaining an output signal from the multi-phase ring oscillator.

20. The method of claim 19 wherein obtaining the output signal comprises receiving four signals that are 90° out of phase with one another.
